(19) United States
(12) Patent Application Publication
(10) Pub. No.: US 2019/0172950 A1
(43) Pub. Date: Jun. 6, 2019

(54) FINFET TRANSISTOR WITH CHANNEL STRESS INDUCED VIA STRESSOR MATERIAL INSERTED INTO FIN PLUG REGION ENABLED BY BACKSIDE REVEAL

(71) Applicant: Intel Corporation, Santa Clara, CA (US)

(72) Inventors: Aaron D. LILAK, Beaverton, OR (US); Sean T. MA, Portland, OR (US); Rishabh MEHANDRU, Beaverton, OR (US); Patrick MORROW, Portland, OR (US); Stephen M. CEA, Hillsboro, OR (US)

(21) Appl. No.: 16/323,661

(22) PCT Filed: Sep. 30, 2016
(86) PCT No.: PCT/US2016/055029

§ 371 Date: Feb. 6, 2019

(51) Int. Cl. H01L 29/78; H01L 27/092; H01L 29/06; H01L 21/8238; H01L 21/762; H01L 29/66

(52) U.S. Cl. CPC H01L 29/7846; H01L 27/0924; H01L 29/0653; H01L 29/6681; H01L 21/823821; H01L 21/823878; H01L 21/76224; H01L 29/785

(57) ABSTRACT

An integrated circuit apparatus including a body; a transistor formed on a first portion of the body, the transistor including a gate stack and a channel defined in the body between a source and a drain; and a plug formed in a second portion of the body, the plug including a material operable to impart a stress on the first portion of the body. A method of forming an integrated circuit device including forming a transistor body on a substrate; forming a transistor device in a first portion of the transistor body on a first side of the substrate; and dividing the transistor body into at least the first portion and a second portion with a plug in the transistor body, the plug including a material operable to impart a stress on the first portion of the body, wherein the material is introduced through a second side of the substrate.

### BACKGROUND

### Field

Integrated circuit processing.

### Description of Related Art

Properly engineered stress (e.g., compressive stress, tensile stress) can improve carrier transport and lead to increased drive current in transistor devices. Prior solutions to engineered stress in a transistor device include the use of an epitaxial stressor materials such as silicon germanium or silicon carbide inserted into or adjacent to source/drain regions on silicon or a silicon germanium on silicon channel device. Another solution induces stress exterior to the device such as above a transistor device.

### BRIEF DESCRIPTION OF THE DRAWINGS

FIG. 1 shows a portion of a semiconductor substrate such as a wafer having a dielectric layer formed thereon into transistor bodies or fins projecting from the dielectric layer.

FIG. 2 shows the structure of FIG. 1 following the division of each fin into a number of transistor device sections.

FIG. 3 shows the structure of FIG. 2 following the front side processing of the structure.

FIG. 4 shows an assembly including the structure of FIG. 3 inverted and bonded to a carrier substrate.

FIG. 5 shows the assembly of FIG. 4 following the removal of substrate to expose the dielectric layer and sacrificial material filling voids in respective fins.

FIG. 6 shows a view of the assembly of FIG. 5 through line 6-6′ and shows the top of the assembly.

FIG. 7 shows the assembly of FIG. 6 following the replacement of sacrificial material with stressor material.

FIG. 8 shows the assembly of FIG. 7 through line 8-8′ and representatively shows the tensile stress applied in a channel region of the device in device area 1300A of fin 130A.

FIG. 9 presents a flow chart of the method of FIGS. 1-8.

FIG. 10 is an interposer implementing one or more embodiments.

FIG. 11 illustrates an embodiment of a computing device.

### DETAILED DESCRIPTION

A technique for introducing engineered stress in a transistor device is described. In one embodiment, the transistor device is a non-planar or three-dimensional transistor device including a transistor body or fin that projects above a level of a dielectric material on a substrate, such as fin field effect transistor (finfet). The technique takes advantage of a practice of forming long fins and dividing of fins in a length direction to allow for multiple devices. In practice, fins are formed on a substrate and then divided along a length dimension by forming voids in the fin. Conventionally, these voids are filled with a dielectric material or otherwise electrically insulating material. According to the technique described herein, the dielectric or other material in the void is replaced with a stressor material that may be referred to as a plug stressor after device processing. The stressor material provides in-line stress (e.g., tensile stress, compressive stress) to a transistor device formed in the fin. The process of replacing the dielectric or the material in the void with a stressor material, in one embodiment, occurs after front-side device fabrication in a backside reveal process.

Advantages to the stress technique described include that the stressor material introduced as a plug into fin voids does not depend upon a lattice mismatch to induce stress and can therefore be integrated with different material systems. Prior art epitaxial stressor techniques require a selection of an appropriate material as an epitaxial stressor for a proposed channel material (e.g., group III-V compound semiconductor, high-germanium, silicon germanium, germanium, etc.). Since the plug stress described does not depend upon lattice mismatch, it can be integrated to provide either tension or compression to a channel and can be integrated in a fashion such that it can provide different stress states for devices of different conductivity (N-type device, P-type device) without relying upon lattice mismatch to do so.

Epitaxial stressors generally exert a force stress within a channel that is generally proportional to a spatial volume of the epitaxial material. As process technologies advance, physical room adjacent to a device to accommodate stressor material declines. As devices shrink the volume of an epitaxial stressor material will generally also be required to shrink making higher stress states more difficult to maintain with scaling using an epitaxial stressor approach.

A further advantage of the plug stress technique described is that it can be used along with other stressing techniques, such as the epitaxial approach or the external stress approach mentioned above.

As noted, the technique described herein implements stress in a fin (e.g., in a channel region of a fin) following device processing and through a backside of the device. The advantage of introducing a stress after a backside reveal as opposed to introducing a stressed material during front side processing is that a material that would be inserted during front side processing would generally requires a coefficient of thermal expansion (CTE) which is similar to a substrate material due to the high temperatures involved in front side processing (e.g., about 1000° C.). Failure to achieve this CTE will make the process more susceptible to yield problems and non-idealities associated with delamination, buckling, etc. Stressor materials with suitable CTEs are accordingly limited. Second, the backside reveal process is believed to be easier to integrate, both due to the removal of the noted CTE problem and also due to a wider choice of materials that are available for a sacrificial material that initially fills the void upon fin division. A third advantage is that stressed materials tend to relax with thermal processing, such as that performed during front side processing. By inserting a stressor material in the plug or voided region of a fin after a backside reveal process and after the thermal processing associated with integrated circuit fabrication, relaxation of the stress material is avoided. Finally, the choice of material to impart the plug stress is greater and can allow for the introduction of even higher-stressed materials than may be possible through a front side integration approach.

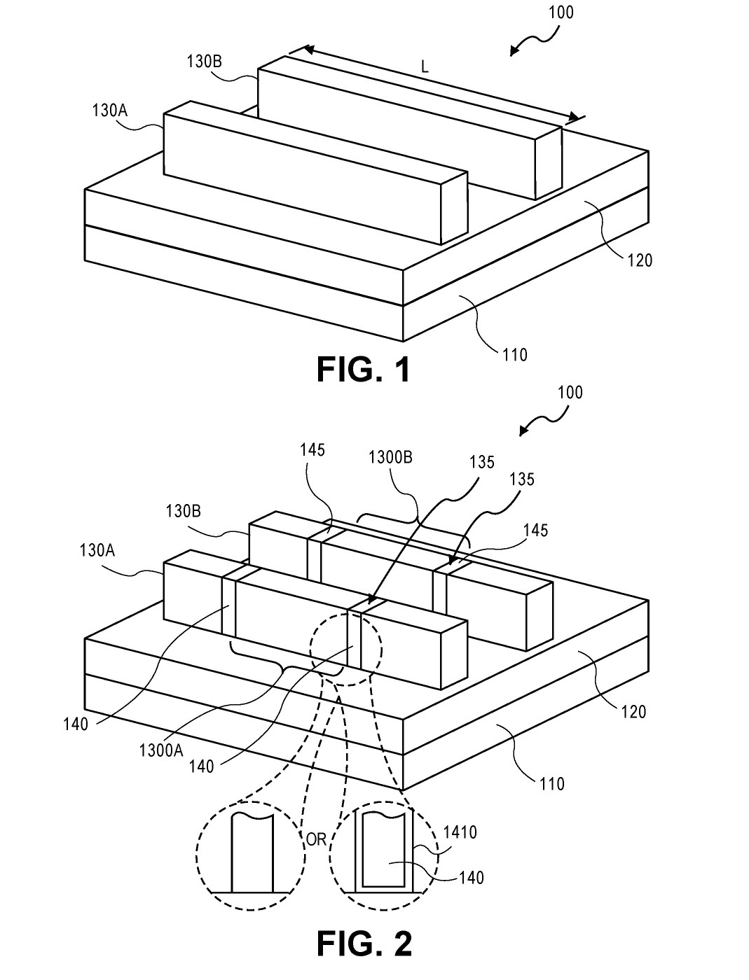

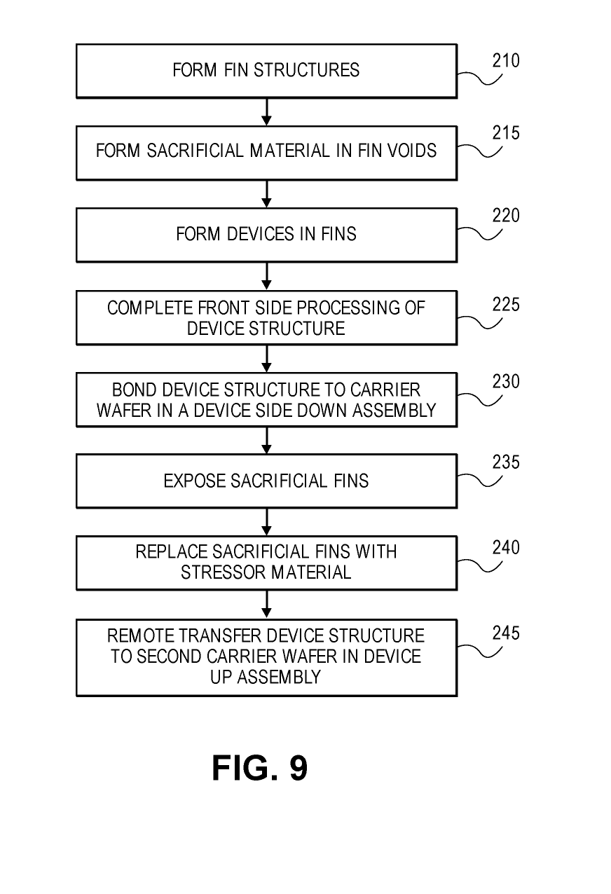

FIGS. 1-8 describe a process of introducing a stressor material into a fin plug region of a three-dimensional transistor body or fin enabled by a backside reveal. FIG. 9 presents a flow chart of the process. FIG. 1 shows a portion of a semiconductor substrate such as a wafer having a dielectric layer formed thereon into semiconductor bodies or fins projecting from the dielectric layer. Referring to structure 100, the structure includes substrate 110 that is, for example, a bulk semiconductor substrate such as silicon or a silicon-on-insulator (SOT) substrate. Substrate 110 may be from a few tens of nanometers into many hundreds of micrometers in thickness and is shown for representative purposes and not to scale. Disposed on a surface of substrate 110 is dielectric layer 120 of, for example, silicon dioxide or a dielectric material having a dielectric constant less than silicon dioxide (a low-k dielectric material) or another electrically insulating material. Projecting from dielectric layer 120 are fin 130A and fin 130B. Fin 130A and fin 130B are, in one embodiment, semiconductor materials selected, for example, as an intrinsic or channel material for transistor devices to be formed in the fin. A material of fin 130A may be different than a material of fin 130B. Representative materials for fin 130A and fin 130B include group III-V compound semiconductors, germanium, (Ge) silicon germanium (SiGe) or silicon (Si). Fin 130A and fin 130B may be formed by patterning a substrate material (e.g., silicon fins patterned in substrate 110 of silicon) and then surrounding the fins with dielectric layer 120 deposited, for example, to a height of fin 130A and fin 130B to define a planar surface of the dielectric layer and the fins then recessing the dielectric layer. Alternatively, fin 130A and fin 130B may be formed by patterning fins from a material of substrate 110 as sacrificial fins, surrounding the sacrificial fins with a dielectric material such as dielectric layer 120 deposited to a height of fin 130A and fin 130B to define in planar surface of the dielectric layer and the fins and then removing the sacrificial fins to form trenches in the surrounding dielectric layer 120. A desired fin material or materials may then be epitaxial grown in the trenches in dielectric layer 120 and the dielectric layer is recessed to expose the fins as shown in FIG. 1 (block 210, FIG. 9). The fins shown in FIG. 1 are rectangular in cross-section (as viewed perpendicular to the length dimension). In practice, the fin may be rectangular, trapezoidal, necked, hourglass or other shape in cross-section as will be apparent to one skilled in the art. Furthermore, the fins shown in FIG. 1 may also include multiple conductive regions separated by insulator layers in a nanowire fin or a nanoribbon fin structure which may also have a cross-sectional shape that is rectangular, trapezoidal, necked, hourglass or other shape as will be apparent to one skilled in the art.

Fins 130A-130B have a length, L, that is longer than that necessary or desired for a transistor device (see FIG. 1). Thus, each fin may be divided into one or more transistor device regions or sections (block 215, FIG. 9). FIG. 2 shows the structure of FIG. 1 following the division of each fin into a number of transistor device sections. The fins are divided by introducing voids 135 in locations along a length dimension of each fin by, for example, a mask and etch process or via the removal of a sacrificial gate structure which is used to pattern the region voided from the fin. For a mask and etch process, voids 135 may be formed in fin 130A and fin 130B prior to recessing dielectric layer 120 to expose the fins. Alternatively, a sacrificial gate structure may be formed on each of fin 130A and fin 130B in areas designated for voids and then the sacrificial gate structure removed, for example, after forming diffusion regions (source and drain) in each fin, and voids formed by an etch process. Voids 135 divide a length of fin 130A into transistor device sections or regions including device region 1300A and fin 130B into transistor device sections or regions including device region 1300B.

FIG. 2 shows sacrificial material 140 in voids 135 of fin 130A and sacrificial material 145 in voids 135 of fin 130B. In one embodiment, sacrificial material 140 is the same as sacrificial material 145 and, in another embodiment, the materials are different. In one embodiment, neither sacrificial material 140 nor sacrificial material 145 needs to be insulating. In one embodiment, a material for sacrificial material 140 and sacrificial material 145, whether the same or different, is any material that has an etch selectively relative to the material of fin 130A and fin 130B, respectively, and relative to dielectric material 120. In another embodiment, where sacrificial material 140 and sacrificial material 145 are different, a material for one may be selectively etched relative to a material for the other (e.g., an etch which removes sacrificial material 140), preferentially to sacrificial material 145, fin materials 130A and 130B and dielectric material 120. In one embodiment, voids 135 in one or both of fin 130A and fin 130B may include a liner layer or etch stop layer. Insets of FIG. 2 shows one void 135 in fin 130A that may include only sacrificial material 140 or may include etch stop or liner layer 1410 surrounding a base and sidewalls of the void and sacrificial material 140 in the void. Representative materials for etch stop or liner layer 1410 include, but are not limited to, a carbide (e.g., silicon carbide), a nitride (e.g., silicon nitride), or an oxide (e.g., aluminum oxide).

In the illustration of sacrificial material 140 and sacrificial material 145 in fin 130A and fin 130B, respectively, the sacrificial material is shown conforming to the shape of the respective fin. It is appreciated that this is representative of an appearance of sacrificial material 140 and sacrificial material 145 such as where the respective sacrificial material is deposited by a selective deposition process into voids 135 so it will grow in the semiconductor region only. An example would be where voids are formed and filled when fin 130A and fin 130B are surrounded by dielectric layer 120 (prior to recessing dielectric layer 120 to expose the fins (see FIG. 1). In such case, dielectric layer 120 can serve to conform sacrificial material 140 to a shape of the respective fin. In other embodiments, sacrificial material 140 and sacrificial material 145 may not conform to the original fin shape but may grow in width and/or height. For example, if voids 135 are formed and filled following a removal of a sacrificial gate structure that was placed in a void area of a fin, the sides of fin 130A or fin 130B are exposed leaving no sidewall containment for a deposition of sacrificial material 145.

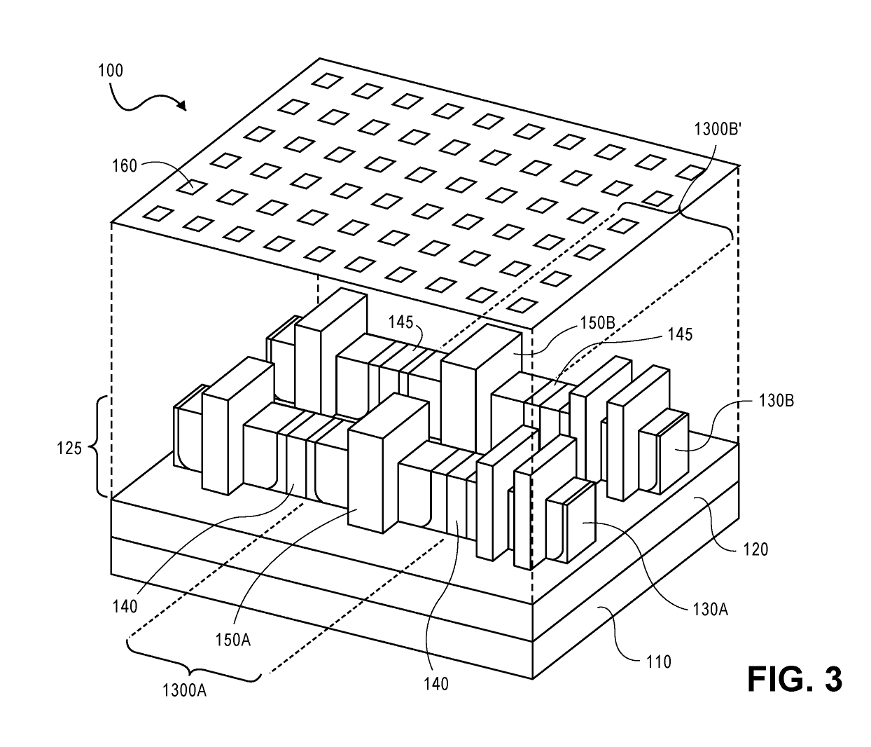

FIG. 3 shows the structure of FIG. 2 following the front side processing of the structure. The front side processing includes forming transistor devices in and on fins 130A and 130B to define device layer 125 (block 220, FIG. 9). Representatively, FIG. 3 shows one transistor device in device region 1300A of fin 130A, the transistor device including gate stack 150A disposed on fin 130A, the gate stack including a gate dielectric and gate electrode. On either side of the gate stack are diffusion regions (source and drain) defining the transistor device. FIG. 3 also shows a transistor device formed in device region 1300B of fin 130B. The transistor device includes gate stack 150B of a gate dielectric and a gate electrode and diffusion regions (source and drain) on either side. As illustrated, the gate stack contacts opposing sides and a top surface of fin 130B as viewed. In one embodiment, the device in device region 1300A of fin 130A is a N-type device and the device in device region 1300B of fin 130B is a P-type device. It is also appreciated that more than one transistor device may be formed in a device region as representatively illustrated by two devices formed in a fin region of each of fin 130A and fin 130B at one end of each fin.

Following the formation of device layer 125 on and in fin 130A and fin 130B, respectively, one or more interconnect levels may be formed on structure 100 and connected to devices in device layer 125. This is followed by the definition of exterior contact layer 160. The forming of interconnect levels and contacts may follow conventional processing techniques (block 225, FIG. 9). FIG. 3 shows the structure with the contacts, interconnect levels and interlayer dielectric material removed.

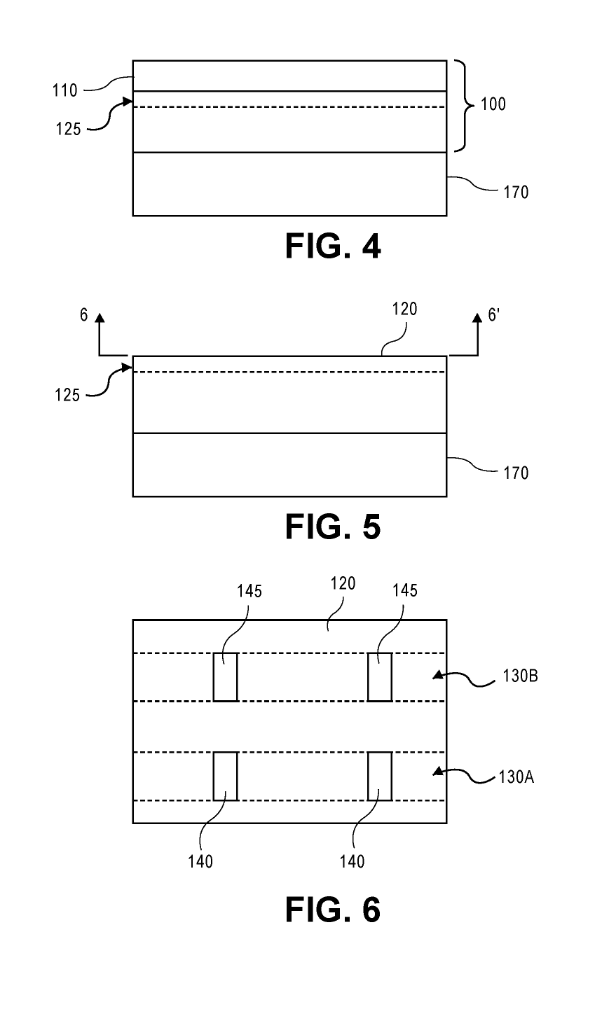

FIG. 4 shows the structure of FIG. 3 following its inversion and bonding device side down to a carrier substrate to form an assembly (block 230, FIG. 9). Carrier substrate 170 is, for example, a wafer size substrate. Structure 100 is bonded device side down so that device layer 125 and interconnects and contacts 160 are disposed between carrier substrate 170 and substrate 110. In this manner, substrate 110 is exposed (a backside of substrate 110 defines a superior surface of the assembly).

FIG. 5 shows the assembly of FIG. 4 following the removal of substrate 110 to expose dielectric layer 120, a backside of fins (e.g., fins 130A and 130B) and the sacrificial material filling voids in respective fins (block 235, FIG. 9). In one embodiment, substrate 110 may be removed by chemical mechanical polish (CMP) process.

FIG. 6 shows a view of the assembly of FIG. 5 through line 6-6′ and shows the top of the assembly. From this view, FIG. 6 shows a top of the assembly including dielectric layer 120 and sacrificial materials 140 and 145 exposed. Where a void in a fin is filled with an etch stop or liner layer such as etch stop or liner layer 1410 optionally filling voids in fin 130A (see FIG. 2), the CMP proceeds until the etch stop or liner layer is exposed.

Following exposure of the sacrificial material or etch stop/liner layer, the sacrificial material may be removed and replaced with a stressor material (block 240, FIG. 9). In one embodiment, a removal of a sacrificial material and replacement with a stressor material may proceed sequentially if, for example, different stressor material is to replace sacrificial material in different fins or in different areas of the same fin or if different sacrificial materials are used for different fins such as for N-type fins and P-type fins. For example, in one sequential processing embodiment, sacrificial material 145 in fin 130B may initially be removed by, for example, forming a mask over an area corresponding to fin 130A or using etch stop or liner layer 1410 (if present) as a mask and then selectively etching sacrificial material 145 relative to dielectric layer 120. Following removal of sacrificial material 145 in fin 130B, the vacated region may be filled with, for example, an electrically non-conductive stressor material (e.g., a highly-stress insulating material) such as a nitride (e.g., silicon nitride). A stressor material may be deposited via chemical vapor deposition (CVD) or other means. It is known that the stressed state of materials such as nitrides are highly dependent upon their deposition condition (e.g., under gas pressure, power, etc.). A deposition condition therefore allows the tuning of the stressed state to be either compressive or tensile depending on the stressed state desired within the channel. In another embodiment, the vacated region may be lined with an electrically insulating lining layer such as an oxide layer and then filled with a highly-stressed core that may be an electrically conductive or non-conductive, such as a stressed tantalum, ruthenium or other layer. For a material such as tantalum, it is known that tantalum may be deposited in either a compressive or tensile state.

Once sacrificial material 145 in fin 130B is replaced with a stressor material, sacrificial material 140 and voids in fin 130A may be exposed and replaced with a different stressor material or the same stressor material with a different or same stress state as would be apparent to one skilled in the art. Where voids in fin 130A are lined with etch stop or liner layer 1410, the material of such voids may be removed by an etchant selected for the etch stop relative to dielectric layer 120 and, perhaps, a stressor material in fin 130B, and then sacrificial material 140 removed with the same etchant or a different etchant. In another embodiment, a mask may be formed over an area corresponding to fin 130B prior to an etch process to remove sacrificial material 140.

The use of an optional insulating liner material or etch stop as shown in layer 1410 as shown in FIG. 2 allows for the use of a stressor material to be inserted within the voided regions 140 and 145 which is highly electrically conductive as would be many metallic stressor layers including, but not limited to, tantalum, ruthenium and tungsten. The inclusion of the liner prevents electrical conduction from occurring along the length direction of the fin such as would occur from the region of 1300A to a region outside of region 1300A. Liner or etch stop material may also serve as an etch stop which will prevent lateral encroachment of the etchant beyond a region which is desired to be voided in the formation of regions 140 and 145.

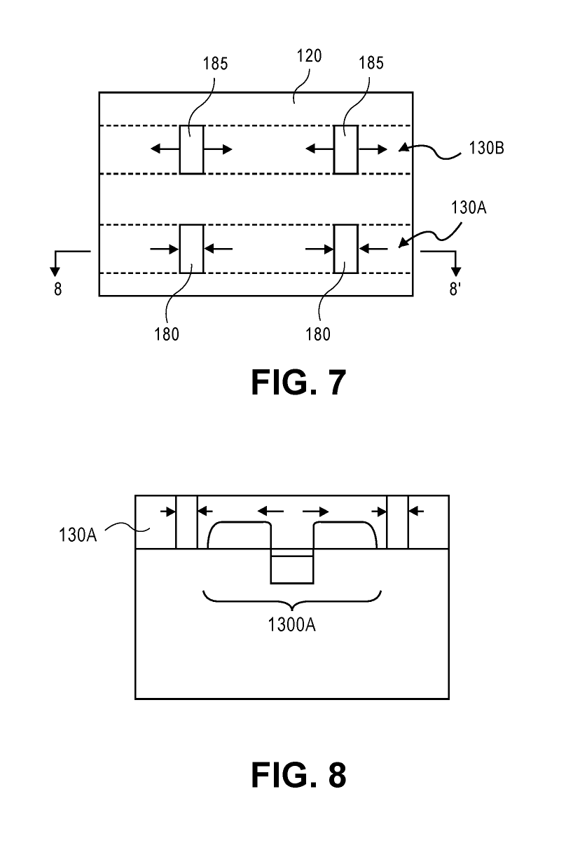

FIG. 7 shows the structure of FIG. 6 following the replacement of sacrificial material with stressor material. In the example of FIG. 7 stressor material 180 in fin 130A applies a tensile stress to the fin body and stressor material 185 in fin 130B provides a compressive stress to the fin body. In the case of stressor material 180, the stressor material induces tension within the channel of a device formed in fin 130A (e.g., a device formed in device area 1300A (see FIG. 3)) and stressor material 185 induces compression within a channel of a transistor device such as a transistor device in device area 1300B (see FIG. 3). FIG. 8 shows the structure of FIG. 7 through line 8-8′ and representatively shows the tensile stress applied in a channel region of the device in device area 1300A of fin 130A. Representatively, a magnitude of an induced stress can be in the range of several hundreds of megapascals for fins having a 3 nanometers to 50 nanometers width and a height dimension of 10 nanometers to 500 nanometers of P-type or N-type with appropriate stressor material.

In the above embodiment, stressor material is introduced in both N- and P-type fins to impart stress on devices previously formed in such fins. In another embodiment, stressor material is only added to one fin through a backside reveal process. Representatively, in current implementations with Si/SiGe/Ge channel devices, it is generally easier to introduce an epitaxial stress to a PMOS device than an NMOS device. Thus, NMOS devices in, for example, fin body 130A and PMOS devices in fin body 130B may each be formed with an epitaxial stress using techniques known in the art. Sacrificial material 145 disposed in voids in fin 130B may not be sacrificial but may be, for example, a dielectric or electrically insulating material while sacrificial material 140 in fin 130A may be a material intended to be removed. Thus, following a backside reveal only sacrificial material 140 is removed and replaced with the stressor material to increase the stress to NMOS devices formed in fin 130A.

Following backside processing to insert stressor material in fin body as desired, where a device layer up assembly is desired, in one embodiment, device layer 125 of the assembly may be transferred to another carrier (block 245, FIG. 9). Device layer 125 may be inverted and attached to another carrier wafer.

In the process described with reference to FIGS. 1-8 and the flow chart of FIG. 9, a stressor material replaces a sacrificial material in voids in a fin. In another embodiment, stressor material is introduced into voids directly rather than in a replacement process. In one embodiment, front side process of structure 100 does not include forming voids 135 and filling the voids with a sacrificial material. Instead, following front side processing, structure 100 is inverted and boded device side down to a carrier substrate (e.g., carrier substrate 170) and a backside of fins exposed. Voids (e.g., voids 135) are then formed in designated areas of fins and a stressor material or a liner layer and stressor material is introduced in the voids. According to this alternative process, the deposition and later removal of sacrificial material can be avoided. In still another embodiment, all voids in fins may be formed after a backside reveal, including voids to be filled with a material other than a stressor material. In a further embodiment, voids serving to separate regions or portions of a fin but not intended to include stressor material may be formed during front side processing while voids designated for stressor material may formed after a backside reveal.

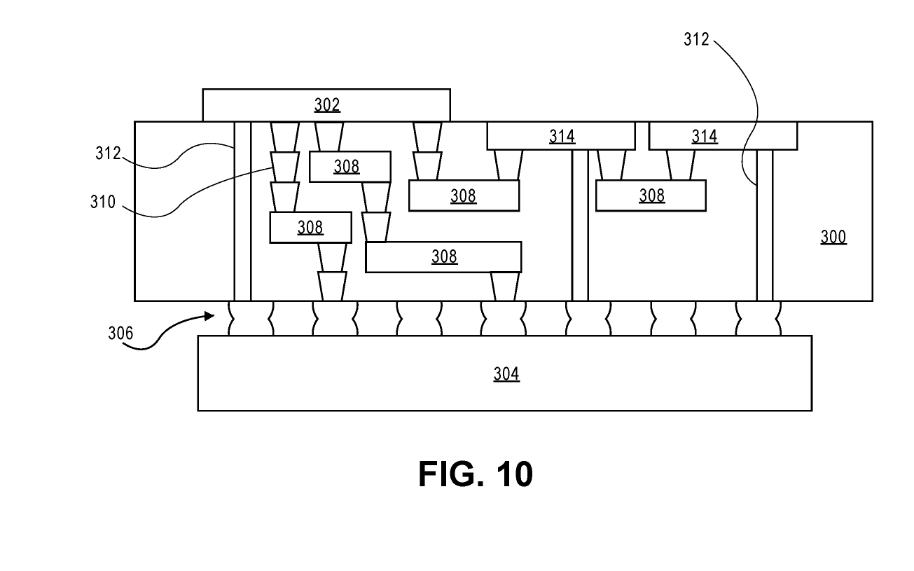

FIG. 10 illustrates interposer 300 that includes one or more embodiments. Interposer 300 is an intervening substrate used to bridge a first substrate 302 to second substrate 304. First substrate 302 may be, for instance, an integrated circuit die. Second substrate 304 may be, for instance, a memory module, a computer motherboard, or another integrated circuit die. Generally, the purpose of interposer 300 is to spread a connection to a wider pitch or to reroute a connection to a different connection. For example, interposer 300 may connect an integrated circuit die to ball grid array (BGA) 306 that can subsequently be connected to second substrate 304. In some embodiments, first and second substrates 302/304 are attached to opposing sides of interposer 300. In other embodiments, first and second substrates 302/304 are attached to the same side of interposer 300. In further embodiments, three or more substrates are interconnected by way of interposer 300.

Interposer 300 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 308 and vias 310, including but not limited to through-silicon vias (TSVs) 312. Interposer 300 may further include embedded devices 314, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on interposer 300.

In accordance with embodiments, apparatuses or processes disclosed herein may be used in the fabrication of interposer 300.

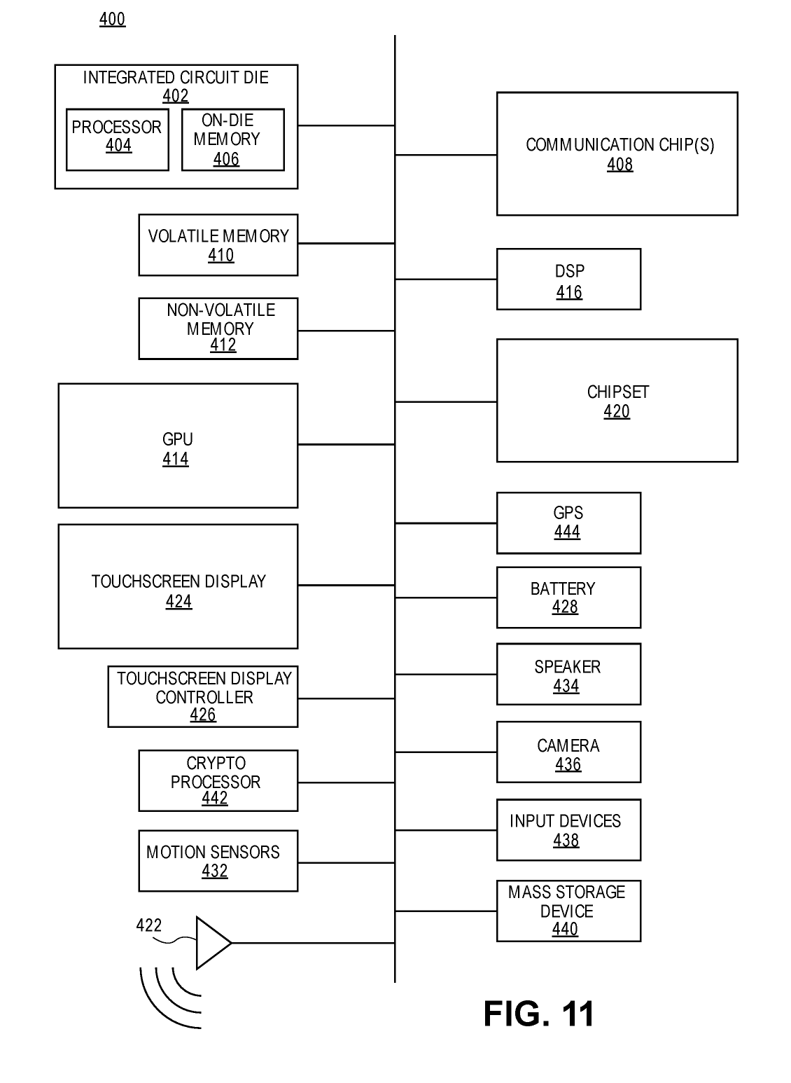

FIG. 11 illustrates computing device 400 in accordance with one embodiment. Computing device 400 may include a number of components. In one embodiment, these components are attached to one or more motherboards. In an alternate embodiment, these components are fabricated onto a single system-on-a-chip (SoC) die rather than a motherboard. The components in computing device 400 include, but are not limited to, integrated circuit die 402 and at least one communication chip 408. In some implementations communication chip 408 is fabricated as part of integrated circuit die 402. Integrated circuit die 402 may include CPU 404 as well as on-die memory 406, often used as cache memory, that can be provided by technologies such as embedded DRAM (eDRAM) or spin-transfer torque memory (STTM or STTM-RAM).

Computing device 400 may include other components that may or may not be physically and electrically coupled to the motherboard or fabricated within an SoC die. These other components include, but are not limited to, volatile memory 410 (e.g., DRAM), non-volatile memory 412 (e.g., ROM or flash memory), graphics processing unit 414 (GPU), digital signal processor 416, crypto processor 442 (a specialized processor that executes cryptographic algorithms within hardware), chipset 420, antenna 422, display or a touchscreen display 424, touchscreen controller 426, battery 428 or other power source, a power amplifier (not shown), global positioning system (GPS) device 444, compass 430, motion coprocessor or sensors 432 (that may include an accelerometer, a gyroscope, and a compass), speaker 434, camera 436, user input devices 438 (such as a keyboard, mouse, stylus, and touchpad), and mass storage device 440 (such as hard disk drive, compact disk (CD), digital versatile disk (DVD), and so forth).

Communications chip 408 enables wireless communications for the transfer of data to and from computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 408 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 400 may include a plurality of communication chips 408. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

Processor 404 of computing device 400 includes one or more devices, such as transistors, that are formed in accordance with embodiments presented above. The term “processor” may refer to any device or portion of a device that processes electronic data from registers and/or memory to transform that electronic data into other electronic data that may be stored in registers and/or memory.

Communication chip 408 may also include one or more devices, such as transistors, that are formed in accordance with embodiments presented above.

In further embodiments, another component housed within computing device 400 may contain one or more devices, such as transistors, that are formed in accordance with implementations presented above.

In various embodiments, computing device 400 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 400 may be any other electronic device that processes data.

### EXAMPLES

Example 1 is an integrated circuit apparatus including a body projecting from a substrate; a transistor formed on a first portion of the body, the transistor including a gate stack contacting at least two adjacent sides of the body and a source and a drain on opposing sides of the gate stack and a channel defined in the body between the source and the drain; and a plug formed in a second portion of the body, the plug including a material operable to impart a stress on the first portion of the body.

In Example 2, the stress of the apparatus of Example 1 is a compressive stress.

In Example 3, the stress of the apparatus of Example 1 is a tensile stress.

In Example 4, the material of the plug of the apparatus of Example 1 includes an electrically insulating material.

In Example 5, the plug of the apparatus of Examples 1-4 is a first plug and the apparatus includes a second plug in a third portion of the body, wherein the first portion of the body is disposed between the second portion and the third portion.

Example 6 is a method of forming an integrated circuit device including forming a transistor body on a substrate projecting from a dielectric layer; forming a transistor device in a first portion of the transistor body on a first side of the substrate; and dividing the transistor body into at least the first portion and a second portion with a plug in the transistor body, the plug including a material operable to impart a stress on the first portion of the body, wherein the material is introduced through a second side of the substrate.

In Example 7, the stress of the method of Example 6 is a compressive stress.

In Example 8, the stress of the method of Example 6 is a tensile stress.

In Example 9, the material operable to impart a stress on the first portion of the body of the method of Example 6 is a second material and the method further includes replacing a first material with the second material.

In Example 10, after forming the transistor body, the method of any of Examples 6-9 includes accessing the transistor body through the substrate.

In Example 11, the substrate of the method of Example 9 includes a first substrate and replacing the first material with a second material includes after forming the transistor body, bonding the first substrate to a second substrate such that the transistor device is disposed between the first substrate and the second substrate; and exposing the transistor body.

In Example 12, exposing the transistor body of the method of Example 10 includes removing a portion of the first substrate.

In Example 13, the material of the method of Examples 6-12 includes an electrically insulating material.

In Example 14, dividing the transistor body into at least a first portion and a second portion of the method of Examples 6-13 includes forming an opening in the transistor body; lining the opening with an etch stop liner; and depositing the first material in the opening.

In Example 15, an integrated circuit device formed by any of the methods of Examples 6-14.

Example 16 is a method of forming an integrated circuit device including forming a plurality of transistor bodies on a substrate projecting from a dielectric layer; dividing each of the plurality of transistor bodies into at least a first portion and a second portion with a plug in the respective transistor body; forming a transistor device in at least one of the first portion and the second portion of each of the plurality of transistor bodies on a first side of the substrate; and replacing the plug with a material through a second side of the substrate, wherein the material is operable to impart a stress on the at least one of the first portion and the second portion of the plurality of transistor bodies.

In Example 17, forming a transistor device in at least one of the first portion and the second portion of each of the plurality of transistor bodies of the method of Example 16 includes forming a first transistor device including a first conductivity type in a first transistor body and a second transistor device including a second conductivity type in a second transistor body and replacing the plug with a material includes replacing the plug with a material operable to impart a compressive stress in the first transistor body and a material operable to impart a tensile stress in the second transistor body.

In Example 18, the substrate of the method of Examples 17 includes a first substrate and replacing the first material with a second material includes after forming the transistor body, bonding the first substrate to a second substrate such that the plurality of transistor devices are disposed between the first substrate and the second substrate; and removing a portion of the first substrate to expose the plurality of transistor devices.

In Example 19, dividing the plurality of transistor bodies into at least a first portion and a second portion of the method of Examples 16-18 includes forming an opening in each of the plurality of transistor bodies; lining the opening with an etch stop liner; and depositing the first material in the opening.

In Example 20, forming a transistor device in at least one of the first portion and the second portion of each of the plurality of transistor bodies of the method of Example 19 includes forming a first transistor device including a first conductivity type in a first transistor body and a second transistor device including a second conductivity type in a second transistor body and lining the opening in each of the plurality of transistor bodies with an etch stop liner includes lining the opening with a first etch stop liner for the first conductivity type and lining the opening with a different second etch stop liner for the second conductivity type.

In Example 21, replacing the plug of the method of Example 20 includes sequentially replacing the plug based on a conductivity type of a transistor device.

In Example 22, the material replacing the plug of the method of Examples 16-21 includes an electrically insulating material.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope, as those skilled in the relevant art will recognize.

These modifications may be made in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An integrated circuit apparatus comprising:
a body projecting from a substrate;
a transistor formed on a first portion of the body, the transistor comprising a gate stack contacting at least two adjacent sides of the body and a source and a drain on opposing sides of the gate stack and a channel defined in the body between the source and the drain; and
a plug formed in a second portion of the body, the plug comprising a material operable to impart a stress on the first portion of the body.

2. The apparatus of claim 1, wherein the stress is a compressive stress.

3. The apparatus of claim 1, wherein the stress is a tensile stress.

4. The apparatus of claim 1, wherein the material of the plug comprises an electrically insulating material.

5. The apparatus of claim 1, wherein the plug is a first plug and the apparatus comprises a second plug in a third portion of the body, wherein the first portion of the body is disposed between the second portion and the third portion.

6. A method of forming an integrated circuit device comprising:
forming a transistor body on a substrate projecting from a dielectric layer;
forming a transistor device in a first portion of the transistor body on a first side of the substrate; and
dividing the transistor body into at least the first portion and a second portion with a plug in the transistor body, the plug comprising a material operable to impart a stress on the first portion of the body, wherein the material is introduced through a second side of the substrate.

7. The method of claim 6, wherein the stress is a compressive stress.

8. The method of claim 6, wherein the stress is a tensile stress.

9. The method of claim 6, wherein the material operable to impart a stress on the first portion of the body is a second material and the method further comprises replacing a first material with the second material.

10. The method of claim 6, wherein after forming the transistor body, the method comprises accessing the transistor body through the substrate.

11. The method of claim 9, wherein the substrate comprises a first substrate and replacing the first material with a second material comprises:
after forming the transistor body, bonding the first substrate to a second substrate such that the transistor device is disposed between the first substrate and the second substrate; and
exposing the transistor body.

12. The method of claim 10, wherein exposing the transistor body comprises removing a portion of the first substrate.

13. The method of claim 6, wherein the material comprises an electrically insulating material.

14. The method of claim 6, wherein dividing the transistor body into at least a first portion and a second portion comprises:
forming an opening in the transistor body;
lining the opening with an etch stop liner; and
depositing the first material in the opening.

15. A method of forming an integrated circuit device comprising:
forming a plurality of transistor bodies on a substrate projecting from a dielectric layer;
dividing each of the plurality of transistor bodies into at least a first portion and a second portion with a plug in the respective transistor body;
forming a transistor device in at least one of the first portion and the second portion of each of the plurality of transistor bodies on a first side of the substrate; and
replacing the plug with a material through a second side of the substrate, wherein the material is operable to impart a stress on the at least one of the first portion and the second portion of the plurality of transistor bodies.

16. The method of claim 15, wherein forming a transistor device in at least one of the first portion and the second portion of each of the plurality of transistor bodies comprises forming a first transistor device comprising a first conductivity type in a first transistor body and a second transistor device comprising a second conductivity type in a second transistor body and replacing the plug with a material comprises replacing the plug with a material operable to impart a compressive stress in the first transistor body and a material operable to impart a tensile stress in the second transistor body.

17. The method of claim 16, wherein the substrate comprises a first substrate and replacing the first material with a second material comprises:
after forming the transistor body, bonding the first substrate to a second substrate such that the plurality of transistor devices are disposed between the first substrate and the second substrate; and
removing a portion of the first substrate to expose the plurality of transistor devices.

18. The method of claim 15, wherein dividing the plurality of transistor bodies into at least a first portion and a second portion comprises:
forming an opening in each of the plurality of transistor bodies;
lining the opening with an etch stop liner; and
depositing the first material in the opening.

19. The method of claim 18, wherein forming a transistor device in at least one of the first portion and the second portion of each of the plurality of transistor bodies comprises forming a first transistor device comprising a first conductivity type in a first transistor body and a second transistor device comprising a second conductivity type in a second transistor body and lining the opening in each of the plurality of transistor bodies with an etch stop liner comprises lining the opening with a first etch stop liner for the first conductivity type and lining the opening with a different second etch stop liner for the second conductivity type.

20. The method of claim 19, wherein replacing the plug comprises sequentially replacing the plug based on a conductivity type of a transistor device.

21. The method of claim 15, wherein the material replacing the plug comprises an electrically insulating material.
